(19) United States
(12) Patent Application Publication
(10) Pub. No.: US 2024/0264432 A1
(43) Pub. Date: Aug. 8, 2024

(54) METHODS AND APPARATUS FOR OPTICAL FIBRE DESIGN AND PRODUCTION

(71) Applicant: UCL Business Ltd., London (GB)

(72) Inventors: Xun Mu, London (GB); Georgios Zervas, London (GB); Alessandro Ottino, London (GB); Filipe Ferreira, London (GB)

(21) Appl. No.: 18/564,461

(22) PCT Filed: May 26, 2022
(86) PCT No.: PCT/GB2022/051343

§ 371 Date: Nov. 27, 2023

(30) Foreign Application Priority Data
May 28, 2021 (GB) 2107657.5

(51) Int. Cl. G02B 27/00; G02B 6/02; G06F 30/20

(52) U.S. Cl. CPC G02B 27/0012; G02B 6/02042; G06F 30/20

(57) ABSTRACT

Aspects of the present disclosure relate to a method of producing data indicative of a multi-core optical fibre configuration, comprising: (a) determining at least one fibre configuration constraint; (b) determining at least one initial parameter set, each initial parameter set comprising a plurality of initial fibre configuration parameters; (c) calculating a fitness value for each initial parameter set; (d) modifying each initial parameter set to produce at least one modified parameter set, said modifying being to improve the fitness value of at least some of the initial parameter sets; (e) iteratively repeating said modifying until it is determined that a ceasing condition is met; (f) determining whether at least one said modified parameter set satisfies the at least one fibre configuration constraint; (g) responsive to said at least one modified parameter set satisfying the at least one fibre configuration constraint, and based on said modified parameter set, generate data indicative of a multi-core optical fibre configuration; and (h) outputting said data.

### BACKGROUND

The present technique relates to the field of design and production of multi-core optical fibres. Multi-core fibres can provide significantly improved capacity relative to single-core fibres. However, the design parameters (for example the composition, number and geometry of the fibre cores) and corresponding transmission properties (for example signal-to-noise ratio and level of crosstalk between cores) relate to each other in many nonlinear ways, both directly and indirectly. The design of a multi-core fibre is thus complex.

Some methods for fibre design utilise a “brute force” approach, for example by modelling a large number of combinations of design parameters. However, this is inefficient, and can lead to optical fibres with suboptimal transmission properties. There is thus a desire for improved methods and apparatus for designing and producing multi-core optical fibres.

### SUMMARY

At least some examples provide a method of producing data indicative of a multi-core optical fibre configuration, the method comprising:
(a) determining at least one fibre configuration constraint;
(b) determining at least one initial parameter set, each initial parameter set comprising a plurality of initial fibre configuration parameters;
(c) calculating a fitness value for each initial parameter set;
(d) modifying each initial parameter set to produce at least one modified parameter set, said modifying being to improve the fitness value of at least some of the initial parameter sets;
(e) iteratively repeating said modifying until it is determined that a ceasing condition is met;
(f) determining whether at least one said modified parameter set satisfies the at least one fibre configuration constraint;
(g) responsive to said at least one modified parameter set satisfying the at least one fibre configuration constraint, and based on said modified parameter set, generate data indicative of a multi-core optical fibre configuration; and
(h) outputting said data.

Further examples provide a n apparatus comprising:
interface circuitry to receive at least one fibre configuration constraint;
calculation circuitry to calculate a fitness value for each of a plurality of initial parameter sets, each said initial parameter set comprising a plurality of initial fibre configuration parameters;
modification circuitry to modify each initial parameter set to produce at least one modified parameter set, said modifying being to improve the fitness value of at least some of the initial parameter sets, and to iteratively repeat said modifying until it is determined that a ceasing condition has been met; and
output generation circuitry to determine whether at least one said modified parameter set satisfies the at least one fibre configuration constraint and to, responsive to said at least one modified parameter set satisfying the at least one fibre configuration constraint, and based on said modified parameter set, generate data indicative of a multi-core optical fibre configuration.
   Further examples provide a computer-readable medium comprising computer-readable instructions which, when executed by at least one processor, cause said processor to perform a method comprising:
(a) determining at least one configuration constraint;
(b) determining at least one initial parameter set, each initial parameter set comprising a plurality of initial configuration parameters;
(c) calculating a fitness value for each initial parameter set;
(d) modifying each initial parameter set to produce at least one modified parameter set, said modifying being to improve the fitness value of at least some of the initial parameter sets;
(e) iteratively repeating said modifying until it is determined that a ceasing condition is met;
(f) determining whether at least one said modified parameter set satisfies the at least one configuration constraint;
(g) responsive to said at least one modified parameter set satisfying the at least one configuration constraint, and based on said modified parameter set, generate output data; and
(h) outputting said data.

Further aspects, features and advantages of the present technique will be apparent from the following description of examples, which is to be read in conjunction with the accompanying drawings.

### BRIEF DESCRIPTION OF THE DRAWINGS

FIG. 1 depicts a cross-section of a multi-core optical fibre.

FIG. 2 depicts a cross section of the region around one a cores of a multi-core optical fibre.

FIG. 3 shows a method for optimising parameters of a multi-core optical fibre.

FIG. 4 shows an example order for stepping through permutations of constraints.

FIG. 5 is a flow chart depicting a method according to an example.

FIG. 6 depicts an apparatus according to an example of the present disclosure.

FIG. 7 depicts a computer-readable medium according to an example.

### DESCRIPTION OF EXAMPLES

An example method will be described, for producing data indicative of a multi-core optical fibre configuration. This data can then be used as an input to a multi-core fibre production process, to produce a multi-core fibre according to the configuration defined in the data.

At least one fibre configuration constraint is determined. For example, this determination may comprise receiving an input from a user, by which the user defines the fibre configuration constraints. As another example, the determination may comprise retrieving at least one fibre configuration constraint from a stored file. The fibre configuration constraints may for example comprise constraints on at least one of: the effective mode area of the fibre, a cut-off wavelength of the fibre, chromatic dispersion in the fibre, crosstalk between cores of the fibre, and coating loss associated with the fibre. These constraints may be limits on permitted values of these parameters, to exclude fibre configurations which lead to non-permitted values. For example, only crosstalk levels below a threshold may be permitted.

At least one initial parameter set is determined. Each such parameter set comprises a plurality of initial fibre configuration parameters. These initial parameters serve as a starting point for an optimisation process. Example parameters include a number of cores, details of the geometry of the cores and other components such as cladding (for example radii and relative positioning), and details of the refractive indices of the cores and other components.

A fitness value is determined for each initial parameter set. This calculation may be based on at least one cost function, each said cost function being associated with at least one of an objective and one or more of the aforementioned fibre configuration constraints. The fitness value thus expresses the “fitness” of the parameter set, such that parameter sets that better satisfy the objective and/or fibre configuration constraints have a higher fitness value.

The one or more initial parameter sets are then modified, to produce at least one modified parameter set. This modifying is to improve the fitness value of at least some of the parameter sets. That is, at least one modified parameter sets are expected to have an improved fitness value relative to their respective initial parameter sets. Examples of such modification are described in more detail below. As an example, the modification may be an iterative optimisation of the fitness values of the parameter sets, for example by applying a metaheuristic optimisation algorithm such as a particle swarm algorithm where each parameter set is a particle of the swarm.

This modifying is iteratively repeated until it is determined that a ceasing condition has been met. The ceasing condition may be a convergence condition, indicating that the iteratively modified fitness values have converged. Alternatively, the ceasing condition may be that a predetermined number of iterations have been performed.

It is then determined whether at least one modified parameter set satisfies the at least one fibre configuration constraint. If so, data indicative of a multi-core optical fibre configuration is generated based on a modified parameter set that satisfies the constraints. For example, the data may comprise the parameters of the modified parameter set. If multiple parameter sets satisfy the constraints, one may be selected based on calculating a transmission quality indicator, such as a maximum capacity or signal to noise ratio, and selecting the parameter set based on this.

Finally, the data is output. For example, the data may be output in a format which is readable by a multi-core fibre production system, which can produce a multi-core fibre according to the data.

In this manner, an improved method for multi-core optical fibre design is provided. By optimising the fibre parameters as described above, significantly improved fibre performance can be provided relative to comparative systems in which, for example, different combinations of fibre parameters are modelled in a brute-force approach without such iterative optimisation.

In some examples, following the aforementioned step in which it is determined whether at least one modified parameter set satisfies the at least one fibre configuration constraint, at least one fibre configuration constraint is updated (e.g. loosened) and the preceding steps (from the determination of the at least one initial parameter set) are repeated at least once. In this way, multiple result parameter sets (each being a modified parameter set that satisfies the at least one fibre configuration constraint) can be determined. The data to be output can then be based on one of these result parameter sets. Thus, the whole method can be iterated, leading to an improved final output parameter set. For example, the fibre configuration constraints can be progressively loosened until a fibre configuration is found which satisfies them. This allows relatively tight constraints to be applied, whilst not being so tight that no result can be found. The result parameter set to be output can be selected by calculating a transmission quality indicator for each result parameter set, and selecting the set to be output based on this.

As explained above, the fitness values may be calculated based on at least one cost function. In one example in which the method steps are repeated as described in the previous paragraph, the cost functions are selected based on determining one or more next fibre configuration constraints to be modified. In this way, the fitness value can be optimised based on the fibre configuration constraints in turn, leading to an improved final fitness value.

Examples of such cost functions include:
a crosstalk cost value, based on a level of crosstalk associated with the given parameter set;
an effective mode area cost value, associated with a fibre core effective mode area associated with the given parameter set;
a cut-off cost value associated with a fibre core wavelength cut-off associated with the given parameter set;
an overlap cost value associated with a fibre core overlap associated with the given parameter set; and
a coating loss cost value associated with a coating loss associated with the given parameter set.

In some examples, it may be determined that the ceasing condition has not been met, despite a predetermined threshold number of iterations having been performed. In this situation, the preceding steps (at least from the determination of the at least one initial parameter set, and optionally including the determination of the at least one fibre configuration constraint) may be repeated, in order use different initial parameters and/or different constraints to attempt to satisfy the ceasing condition. The chance of failing to identify a suitable fibre configuration is thus reduced, and the likelihood of ultimately determining an optimised fibre configuration.

In an example, it may be determined that no modified parameter sets satisfy the at least one fibre configuration constraint. In this situation, that constraint may be updated (e.g. loosened), after which the preceding steps from the determination of the at least one initial parameter set are repeated, in an attempt to find a configuration which satisfies the constraint. This significantly improves the chances of ultimately determining an optimised fibre configuration, by progressively loosening the constraints (similarly to the loosening described above). This step may optionally be additionally responsive to determining that a predefined number of iterations have been performed, i.e. that a number of iterations have been performed without finding a configuration that satisfies the constraints. The efficiency of the overall method, in particular its ability to efficiently arrive at an optimised set of parameters, is thereby increased.

It is described above that the method may be iterated following an updating of at least one of the fibre configuration constraints. This updating may for example comprise iteratively modifying an effective mode area constraint and a cut-off wavelength constraint and optimizing a level of crosstalk at each combination of the effective mode area constraint and the cut-off wavelength constraint, and iteratively modifying the cut-off wavelength and optimizing the effective mode area at each cut-off wavelength. This provides an effective way of modifying the constraints to optimise the determined sets of parameters.

Examples of the present disclosure will now be described with reference to the drawings.

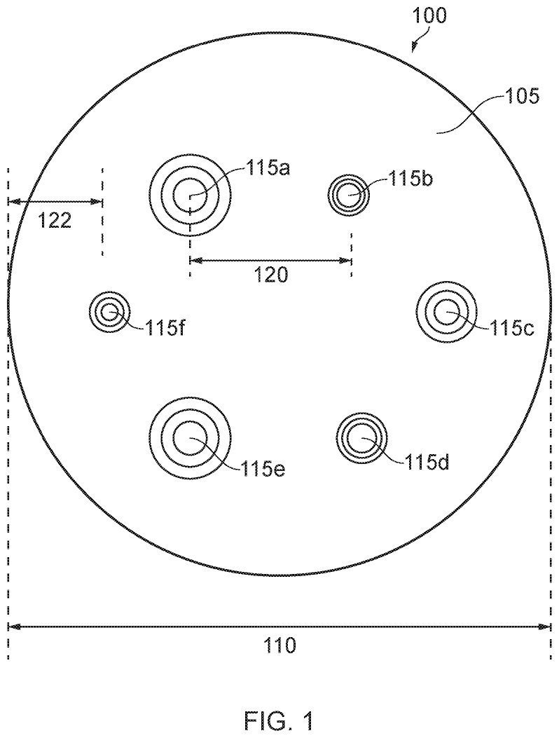

FIG. 1 schematically shows a cross-section of a multi-core optical fibre 100. The multi-core fibre comprises cladding 105 with diameter 110, within which are situated multiple cores 115a-115f. In this example, the cores 115a-115f are regularly positioned around the central axis. Their layout can thus be characterised by three values: the number of cores (6 in this example), the inter-core separation (the core pitch) 120, and the perpendicular distance from the central axis of a core to the edge of the cladding (the outer cladding diameter) 122. The core pitch and outer cladding diameter may be selected to maximise the amount of cladding which surrounds each core.

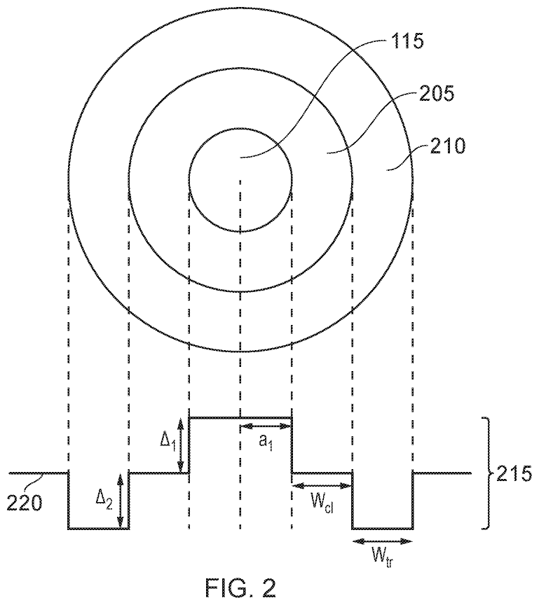

FIG. 2 depicts, in more detail, a cross section of the region around one of the cores 115 of FIG. 1. The core 115 itself is the main component in which data is transmitted. It is surrounded by inner cladding 205, which is in turn surrounded by a trench 210. The combined assemblage sits within the cladding 105 as shown in FIG. 1.

The core and its surrounding components can be characterised by five parameters 215. These parameters are:
The radius a₁ of the core 115;
The width w_{cl} of the inner cladding 205;
The width wₜᵣ of the trench 210;
The difference Δ₁ between the refractive index of the core and the refractive index of the inner cladding 205; and
The difference Δ₂ between the refractive index of the inner cladding 205 and the refractive index of the trench 210.

Each core 115a-f may have different values of the above-described parameters (as shown in FIG. 1, in which the width of each component varies from core to core.

The profile of the above-mentioned refractive indices is shown by solid line 220. It can be seen that, in this example, the inner cladding 205 has a lower refractive index than the core 115, and the trench 210 has a lower refractive index than the inner cladding 210. Furthermore, in this example the inner cladding 205 has the same refractive index as the main cladding 105 (for example because it is made from the same material, e.g. silica).

Changing these parameters causes non-trivial changes to the overall data transmission properties of the multi-core fibre, such as signal-to-noise ratio and capacity. Aspects of the present disclosure allow these parameters to be optimised, providing significantly improved transmission properties relative to cores designed using comparative examples. For example, some comparative examples may use a brute force approach. Such a brute force approach may need to evaluate a number of the order of 10¹⁵ permutations of the parameters. To evaluate so many permutations is practically impossible with modern processing apparatuses, meaning that such an approach is likely to produce a sub-optimal result. The present disclosure, conversely, allows this number to be reduced to the order of 10⁵, thereby allowing an optimal (or close-to-optimal) configuration to be determined. Aspects of the present disclosure also significantly reduce the time to evaluate each permutation, further reducing the overall computational requirements.

In order to reduce the search space, certain parameters may be pre-defined. For example, the diameter 110 of the external cladding 105 may be set to a standard value such as 125 μm. In this example, the outer cladding diameter 122 may be set to 30 μm as larger values would cause non-negligible coating loss. The core pitch 120 may accordingly be set to 32.5 μm to maximise separation between the cores 115a-115f.

Mechanical feasibility constraints may also be applied. For example, the distance between the edges of adjacent trenches 210 may be limited to being 2 μm or larger, to prevent adjacent cores from overlapping with each other. A limit may also be applied on the coating loss, such as 0.001 dB/km.

Certain properties of the components may also be assumed. In one example, it may be assumed that the core 115 is doped with germanium, the trench is doped with fluorine, and the cladding (both internal 205 and external 105) has the refractive index of pure silica.

In this example it may further be assumed that cores 115a, 115c and 115e have the same parameter values, and likewise that cores 115b, 115d, and 115f have the same parameter values (which may be different to those of cores 115a, 115c and 115e). This may increase overall performance of the multi-core fibre 100.

Thus, in an example in which the above-described constraints and assumptions are applied, each potential configuration of the multi-core fibre may be fully characterised by 10 variables (a₁, w_{cl}, wₜᵣ, Δ₁, and Δ₂ for cores 115a, 115c, 115e, and likewise for cores 115b, 115d, 115f). Bearing in mind the constraints above, the following table shows the acceptable ranges for these parameters, along with an example step size for stepping through the possible values, and the consequent number of choices as to the value of each parameter.

| Parameter | Range | Step | Choices |
|---|---|---|---|
| a₁ [μm] | 4~6 | 0.1 | 21 |
| w_{cl} [μm] | 2.5~7.5 | 0.1 | 51 |
| wₜᵣ [μm] | 2.5~7.5 | 0.1 | 51 |
| Δ₁ | 0.3%~−0.6% | 0.01% | 31 |
| Δ₂ | −0.7%~−0.35% | 0.01% | 36 |

Inter-core crosstalk in a multi-core fibre is the power leakage to a given core, from adjacent cores. The crosstalk of core p can be expressed as:

$$IC - {XT}_{p} = \frac{n - {\sum }_{i = 1}^{n} {e}^{- ( n + 1 ) {h}_{pq} L}}{1 + {\sum }_{i = 1}^{n} {e}^{- ( n + 1 ) {h}_{pq} L}}$$

Where q is any of the n neighbours of target core p, L is the fibre length, and h_{pq} is the average power coupling coefficient between cores p and q. If the multi-core fibre is homogeneous (i.e. the parameters discussed above have the same value for each core), h^{pq} is the same for each pair of neighbouring cores.

The mean inter-core crosstalk, across all cores, can be considered the overall crosstalk: this can be used as an optimisation parameter as discussed in more detail below.

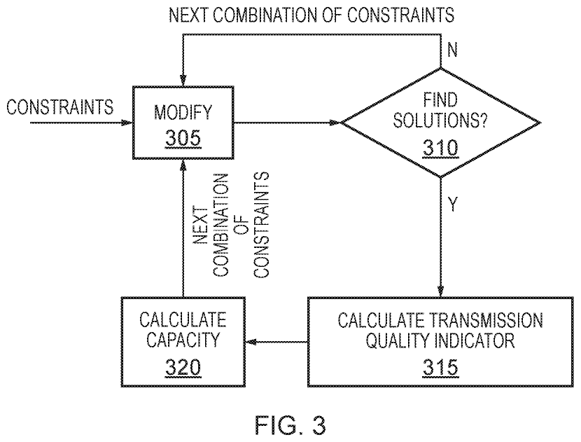

FIG. 3 shows a method for optimising parameters such as those described above.

At block 305, a set of constraints is received, and an initial set of parameters is modified. This modification may for example be one iteration of an optimisation process such as a particle swarm optimisation, to optimise the parameters. This may be a crosstalk optimisation, with the aim of minimising crosstalk.

As an example, the constraints may be constraints on the cut-off wavelength (i.e. bandwidth of the fibre) and modal effective area Δ_{eff} (which is inversely proportional to the nonlinear interference). These values depend on the refractive index profile of the fibre core, and the core distribution. Example cut-off wavelength constraints include:
1. ≤1530 nm (such that the multi-core fibre can cover the C+L band);
2. ≤1460 nm (such that the multi-core fibre can cover the S+C+L band);
3. ≤1360 nm (such that the multi-core fibre can cover the E+S+C+L band);

Similarly, various constraints on Δ_{eff} are possible, for example five sub-ranges within the range from 70 to 100 μm².

At block 310, it is determined whether the modification (e.g. particle swarm optimisation) arrives at a solution which satisfies the constraints (for example within a given number of runs, such as 10 runs of a particle swarm optimisation process). If not, flow returns to block 305 where a new combination of constraints is applied. For example, the possible permutations of wavelength cut-off constraint and Δ_{eff} constraint may be stepped through in turn.

If a solution is found, flow proceeds to block 315 where a transmission quality indicator, such as signal-to-noise ratio, is determined for the solution set of parameters. This may for example be based on an inter-channel stimulated Raman scattering (ISRS) Gaussian noise (GN) model. The corresponding capacity is then calculated at block 320, after which the process is repeated with the next set of constraints.

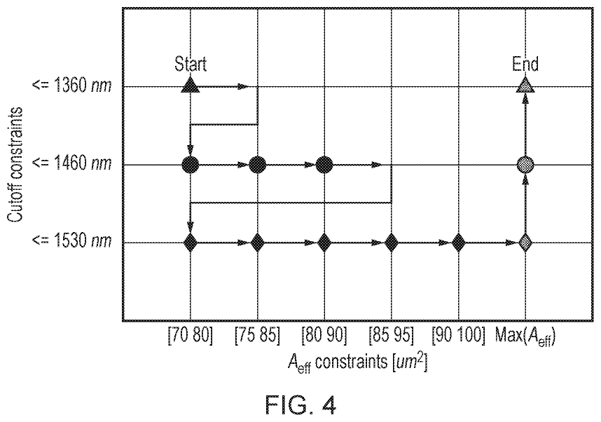

FIG. 4 shows an example order for stepping through the possible permutations of the above-described wavelength cut-off and Δ_{eff} constraints. It can be seen that block 305 of FIG. 3 (the modification, e.g. particle swarm optimisation) is initially performed for the shortest cut-off wavelength constraint and the smallest Δ_{eff} constraint. If a solution is not reached in 10 runs, the method moves to a higher wavelength cut-off constraint while starting from the smallest Δ_{eff} constraint. Then, and if within ten runs solutions are found satisfying all the constraints, the same cut-off wavelength constraint is kept and the method moves to the next highest Δ_{eff} constraint, until the Δ_{eff} constraint cannot be satisfied. In some examples, when the above-described crosstalk optimization is done, a further series of optimisations is performed by modifying the parameters to optimise Δ_{eff}. These optimisations can use different objective functions, as described in more detail below.

The maximum Δ_{eff} is then searched with an optimisation process one by one for three cut-off wavelength constraints. For solutions satisfying all the constraints, SNR and capacity are calculated.

### Particle Swarm Optimisation

An example particle swarm optimisation process will now be described.

Each particle xₚ₁=(xₚ₁, xₚ₂, . . . , xₚₘ) in the swarm can be regarded as one potential solution (a multi-core fibre structure) which includes m=10 dimensions (i.e. two of each of the five parameters, as discussed above). With each solution, there is a corresponding fitness value calculated with an objective function. This is utilised to indicate how this solution performs. By comparing the fitness values, firstly the particle needs to think as an independent individual about the best solution that the particle itself finds so far which is denoted as p_{best}. Simultaneously, as a social group, particles communicate with each other. The best solution obtained with the global group's discussion is called g_{best}. Both self-thinking and social communication influence the final decision on how to optimize. The optimization direction is described by the velocity vₚ=(vₚ₁, vₚ₂, . . . , vₚₘ).

During the optimization process, each particle adjusts appropriately its optimization direction at each iteration. An inertia factor, I, may be applied, which changes with the iteration dynamically to improve the local search precision. In this example, it may decrease from 1 to 0.1 linearly from the beginning to the maximal iterations.

$${ω}_{i} = {ω}_{max} - \frac{i ( {ω}_{max} - {ω}_{min} )}{{i}_{max}} ,$$

$${v}_{P}^{i} = ω {v}_{P}^{i - 1} + {c}_{1} \cdot s \cdot ( {p}_{best}^{i - 1} - {x}_{p}^{i - 1} ) + {c}_{2} \cdot s \cdot ( {g}_{best}^{i - 1} - {x}_{P}^{i - 1} )$$

$${x}_{P}^{i} = {x}_{P}^{i - 1} + {v}_{P}^{i} .$$

(p_{best}ⁱ⁻¹−xₚⁱ⁻¹) is a cognition component and (g_{best}ⁱ⁻¹−xₚⁱ⁻¹) is a social component. Let s be a 1×m-dimension matrix of realisations of the random variable S˜N(0, 1). The constants c₁ and c₂ determine the weight and in turn the influence of the two components on the velocity. They may be referred to as learning rates. Generally c₁=c₂=2. vₘₐₓ is used to constrain the velocity, where vₘᵢₙ=−vₘₐₓ and vₘₐₓ=0.2*(ub−lb) to provide a 20% dynamic range for the particles' activity.

In the crosstalk optimisation process described above, the particle number may be set as 100 while the maximal iteration number is set as 500. In the Δ_{eff} optimisation process, particle number is set as 200 while the maximal iteration number is kept the same. A convergence criterion may be employed to judge the particles' status, such that if more than 99% particles hold the same value as the g_{best}, it is considered that the swarm has lost its exploration ability and converged; the optimization process is then stopped.

### Coating Loss Classifier and Regressor

An example coating loss classifier and regressor will now be described.

The coating loss is defined as the outermost core's bending loss of LP01 at 1625 nm with R_{b}=140 mm with coating index as 1.475. To speed up computation of coating loss a statistical classifier may be used to check whether or not the coating loss of the core is higher than 1e-3 dB/km. If it is higher than the threshold, the regressor is utilized to check the magnitude of the coating loss. A finite difference eigenmode (FDE) solver such as Lumerical can be used to solve the mode and calculate the loss.

A classifier may be implemented using a 5-layer fully-connected neural network trained with 7000 cases generated with the FDE solver. The data can be split into three parts: 50% for training, 25% for validation and 25% for test.

A regressor can be implemented using a 4-layer fully-connected neural network. The data can be split into three parts: 40% for training, 30% for validation and 30% for test.

Such a classifier has a high level of accuracy, and such a regressor has a low mean square error.

### Objective Functions

As explained above, the optimisation process (such as a particle swarm optimisation) may be based on fitness values calculated by way of objective functions. Examples of such functions will now be described.

An objective function contains design requirements, and returns a fitness value to the optimisation process for every particle so that the optimization direction can be adjusted properly according to the fitness value. In this example, two objective functions are used, 1) focusing on optimizing crosstalk with strict constraints on Δ_{eff} and cut-off wavelength (termed XT-optimisation) and 2) purely aiming at maximizing Δ_{eff} for a particular cut-off wavelength (termed Δ_{eff} optimisation).

The objective function checks the following constraints in order. The first two are the the above-described basic conditions: non-overlap of cores, and coating loss. Hence, if they are not satisfied, the particle will be treated as invalid and the fitness value will be returned as:

$$fitness value = {Cost}_{overlap} + {Cost}_{coat}$$

When they are both satisfied, the valid particles have different objective functions in XT-optimisation and Δ_{eff} optimisation. The fitness value in the XT-optimization case is:

$$fitness value = XT + {Cost}_{{A}_{eff}} + {Cost}_{cutoff}$$

A conversely the fitness value for Δ_{eff} optimization is:

$$fitness value = - \sum {A}_{eff} + {Cost}_{cutoff}$$

The cost terms will now be described.

1) If the distance between the adjacent trench is smaller than 2 m, overlap_{pq}=CP_{pq}−(a_{3,p}+a_{3,q}+2) will be smaller than zero. p and q are the core IDs of the neighbouring core pair. If overlap_{pq} is below zero, the fitness value suffers a penalty: Costₒᵥₑᵣₗₐₚ=(overlap_{pq}*1e5)². Otherwise, Cost₀ᵥₑᵣₗₐₚ=0.

2) The above-described coating loss classifier is firstly used to check if the outer core has a coating loss higher than the threshold. If the output of classifier is higher than 0.5, the regressor is used to estimate the magnitude of coating loss and the fitness value suffers a

$${{Cost}_{coat} = ( \sum - 3.2 - CoatingLoss ) * 2 e 5 )}^{2}$$

in which CoatingLoss is the regressor's output for each core.

3) If the cut-off wavelength of the core is higher than the design constraints, the fitness value suffers a penalty: if cut-off>1530 nm,

$${Cost}_{cutoff} = {( \sum cutoff - 1530 * 2.05 )}^{2}$$

taking 1530 nm as the example. Otherwise, Cost_{cutoff}=0.

4) The A_{eff} at 1550 nm is constrained in a range, for instance, between 75 and 85 μm², to offer choices for heterogeneous structure while keeping A_{eff} close to each other. If the core holds a Δ_{eff} higher than 85 μm², Cost_{A}_{_{eff}}=((A_{eff}−85)*50)² If the core holds a Δ_{eff} smaller than 75 μm², Cost_{A}_{_{eff}}=((75−A_{eff})*50)².

The above provides an effective and mathematically efficient way of expressing the fitness of a given combination of parameters, within the above-described optimisation process.

### SNR and Capacity

As noted above, one example of a transmission quality indicator which may be calculated at block 315 of FIG. 3 is signal-to-noise ratio (SNR). An example will now be described by which SNR (and capacity, per block 320 of FIG. 3) can be calculated.

The SNR and capacity performance of the solutions output by the optimisation process (blocks 305 and 310) are calculated using the above-mentioned ISRS GN model while taking crosstalk into consideration. Since some multi-core fibres have bandwidths wider than 15 THz, the Raman gain coefficient (Cr) cannot be approximated as a constant. Therefore, the Raman equations can be solved to obtain the actual power profile and then match it to these power profile to get Cr. Under the assumption that the channels have uniform launch power, SNR in the presence of crosstalk can be approximated by:

$$S N R = {( S N {R}_{0}^{- 1} + XT )}^{- 1}$$

n which SNR₀ is the SNR calculated without XT, wherein XT refers to the crosstalk with neighbouring cores. The capacity of a multi-core fibre can be calculated as

$$Capacity = {\sum }_{j}^{{N}_{c}} {\sum }_{i}^{N} Bch \cdot {log}_{2} ( 1 + S N {R}_{i} )$$

in which N_{c} is the number of cores in the multi-core fibre, B_{ch} is the bandwidth of each channel and N is the total number of wavelength channels in each core.

Efficient methods for designing (and, subsequently, producing) an optimised multi-core optical fibre have thus been described. A skilled person will appreciate that such a method provides a significant advantage over comparative examples in which, for example, computing resource limitations mean that only a subset of fibre parameters can be considered. The present method considers all the fibre parameters together, solving this multi-dimensional and multi-constraint problem in a computationally efficient manner, thereby improving the properties of the consequent multi-core fibres. There are numerous complex and non-linear relationships between the fibre design parameters and the theoretical maximum capacity, and the present disclosure takes these into account in a computationally efficient manner.

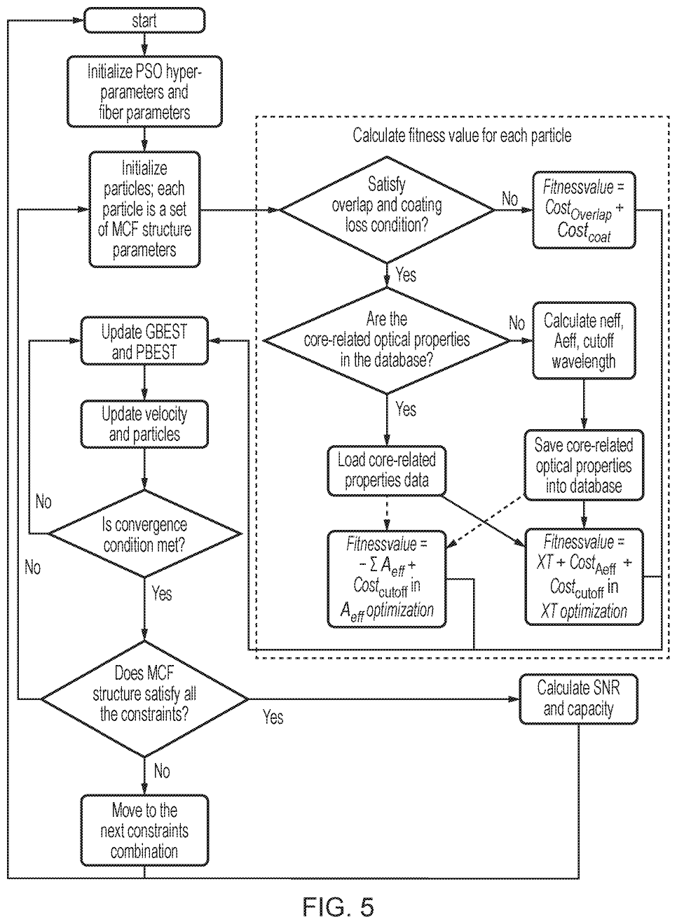

An example of such a method is summarised in FIG. 5, which a flow chart illustrating an example method as described above.

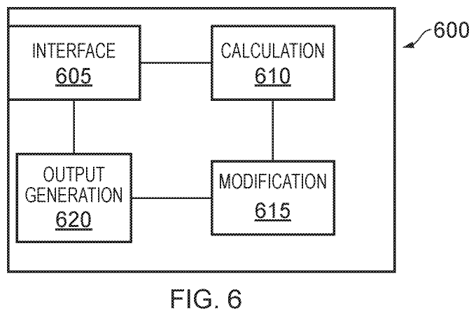

FIG. 6 schematically illustrates an apparatus 600 according to an example of the present disclosure.

The apparatus comprises interface circuitry 605 to receive at least one fibre configuration constraint.

The apparatus comprises calculation circuitry 610 to calculate a fitness value for each of a plurality of initial parameter sets, each said initial parameter set comprising a plurality of initial fibre configuration parameters.

The apparatus comprises modification circuitry 615 to modify each initial parameter set to produce at least one modified parameter set, said modifying being to improve the fitness value of at least some of the initial parameter sets, and to iteratively repeat said modifying until it is determined that a ceasing condition has been met

The apparatus comprises output generation circuitry 620 to determine whether at least one said modified parameter set satisfies the at least one fibre configuration constraint and to, responsive to said at least one modified parameter set satisfying the at least one fibre configuration constraint, and based on said modified parameter set, generate data indicative of a multi-core optical fibre configuration.

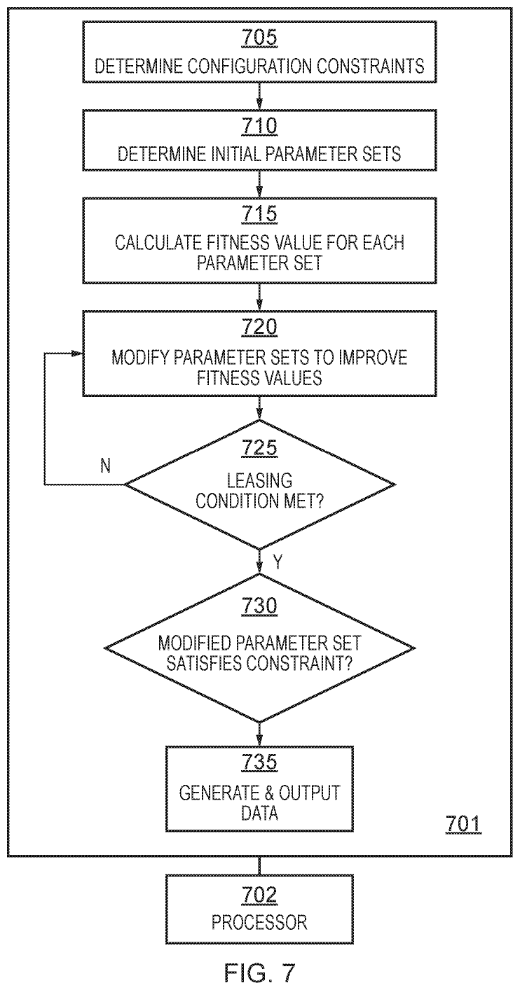

FIG. 7 schematically illustrates a computer-readable medium 701 communicatively coupled with a processor 702. The medium 701 may for example be a non-transitory medium such as a storage, or a transitory medium such as a carrier wave or transmission medium.

The medium 701 comprises instructions 705-735 which, when executed by the processor 702, cause the processor to perform a method according to examples of the present disclosure. The method comprises:
(705) determining at least one configuration constraint;
(710) determining at least one initial parameter set, each initial parameter set comprising a plurality of initial configuration parameters;
(715) calculating a fitness value for each initial parameter set;
(720) modifying each initial parameter set to produce at least one modified parameter set, said modifying being to improve the fitness value of at least some of the initial parameter sets;
(725) iteratively repeating said modifying until it is determined that a ceasing condition is met;
(730) determining whether at least one said modified parameter set satisfies the at least one configuration constraint;
(735) responsive to said at least one modified parameter set satisfying the at least one configuration constraint, and based on said modified parameter set, generate output data, and (h) outputting said data.

The skilled person will thus appreciate that whilst examples above have been illustrated with reference to multi-core fibres, aspects of the present disclosure are more general and can be applied to designing configurations of other complex systems.

In the present application, the words “configured to . . . ” are used to mean that an element of an apparatus has a configuration able to carry out the defined operation. In this context, a “configuration” means an arrangement or manner of interconnection of hardware or software. For example, the apparatus may have dedicated hardware which provides the defined operation, or a processor or other processing device may be programmed to perform the function. “Configured to” does not imply that the apparatus element needs to be changed in any way in order to provide the defined operation.

Although illustrative embodiments of the invention have been described in detail herein with reference to the accompanying drawings, it is to be understood that the invention is not limited to those precise embodiments, and that various changes and modifications can be effected therein by one skilled in the art without departing from the scope of the invention as defined by the appended claims.

1: A method of producing data indicative of a multi-core optical fibre configuration, the method comprising:
(a) determining at least one fibre configuration constraint;
(b) determining at least one initial parameter set, each initial parameter set comprising a plurality of initial fibre configuration parameters;
(c) calculating a fitness value for each initial parameter set;
(d) modifying each initial parameter set to produce at least one modified parameter set, said modifying being to improve the fitness value of at least some of the initial parameter sets;
(e) iteratively repeating said modifying until it is determined that a ceasing condition is met;
(f) determining whether at least one said modified parameter set satisfies the at least one fibre configuration constraint;
(g) responsive to said at least one modified parameter set satisfying the at least one fibre configuration constraint, and based on said modified parameter set, generate data indicative of a multi-core optical fibre configuration; and
(h) outputting said data.

2: The method according to claim 1, wherein the calculating the fitness value for a given parameter set is based on at least one cost function, each said cost function being associated with at least one of an objective and one or more fibre configuration constraints.

3: The method according to claim 1, comprising, following step (f), updating said at least one fibre configuration constraint, and repeating steps (b) to (f) at least once, to determine at least one result parameter set, each result parameter set being one of said modified parameter sets having an associated transmission quality indicator, and wherein the modified parameter set of step (g) comprises said at least one result parameter set.

4: The method according to claim 3, wherein the transmission quality indicator is a signal-to-noise ratio.

5: The method according to claim 3, wherein the calculating the fitness value for a given parameter set is based on at least one cost function, each said cost function being associated with at least one of an objective and one or more fibre configuration constraints, the method further comprising selecting one or more cost functions based on determining one or more next fibre configuration constraints to be updated.

6: The method according to claim 2, wherein said at least one cost function comprises at least one of:
a crosstalk cost value, based on a level of crosstalk associated with the given parameter set;
an effective mode area cost value, associated with a fibre core effective mode area associated with the given parameter set;
a cut-off cost value associated with a fibre core wavelength cut-off associated with the given parameter set;
an overlap cost value associated with a fibre core overlap associated with the given parameter set; and
a coating loss cost value associated with a coating loss associated with the given parameter set.

7: The method according to claim 1, wherein said modifying comprises performing an iterative optimisation of the fitness values of the parameter sets.

8: The method according to claim 7, comprising performing said optimisation by applying a metaheuristic optimisation algorithm.

9: The method according to claim 8, wherein said metaheuristic optimisation algorithm is a particle swarm optimisation algorithm, wherein each parameter set is a particle of said particle swarm.

10: The method according to claim 1, wherein said ceasing condition is a convergence condition, indicating that said fitness values have converged.

11: The method according to claim 1, further comprising, responsive to determining in step (e) that:
a predetermined threshold number of iterations has been performed; and
the ceasing condition has not been met,
repeating at least steps (b) to (e).

12: The method according to claim 1, wherein said modifying is to improve the fitness value of at least one of said parameter sets.

13: The method according to claim 1, further comprising, responsive to determining in step (f) that no modified parameter sets satisfy the at least one fibre configuration constraint:
updating said at least one fibre configuration constraint; and
repeating steps (b) to (f).

14: The method according to claim 13, wherein said updating the at least one fibre configuration constraint and repeating steps (b) to (f) is additionally responsive to determining, at step (f), that a predefined threshold number of iterations have been performed in step (e).

15: The method according to claim 3, wherein updating the at least one fibre configuration constraint comprises loosening at least one constraint of the plurality.

16: The method according to claim 1, wherein said at least one fibre configuration constraint comprises a constraint on at least one of:
effective mode area;
cut-off wavelength;
chromatic dispersion;
crosstalk;
coating-loss;

17: The method according to claim 16, wherein updating said at least one fibre configuration constraint comprises:
iteratively modifying the effective mode area constraint and the cut-off wavelength constraint and optimizing a level of crosstalk at each combination of the effective mode area constraint and the cut-off wavelength constraint; and
iteratively modifying the cut-off wavelength and optimizing the effective mode area at each cut-off wavelength.

18: The method according to claim 1, wherein improving a given fitness value comprises causing said given fitness value to indicate improved fitness.

19: The method according to claim 1, comprising constructing a multi-core optical fibre based on said data.

20: The method according to claim 1, wherein each initial parameter set, and the output data, comprises parameters indicative of a physical layout of a multi-core optical fibre.

21: An apparatus comprising:
interface circuitry to receive at least one fibre configuration constraint;
calculation circuitry to calculate a fitness value for each of a plurality of initial parameter sets, each said initial parameter set comprising a plurality of initial fibre configuration parameters;
modification circuitry to modify each initial parameter set to produce at least one modified parameter set, said modifying being to improve the fitness value of at least some of the initial parameter sets, and to iteratively repeat said modifying until it is determined that a ceasing condition has been met; and
output generation circuitry to determine whether at least one said modified parameter set satisfies the at least one fibre configuration constraint and to, responsive to said at least one modified parameter set satisfying the at least one fibre configuration constraint, and based on said modified parameter set, generate data indicative of a multi-core optical fibre configuration.

22: A computer-readable medium comprising computer-readable instructions which, when executed by at least one processor, cause said processor to perform a method comprising:
(a) determining at least one configuration constraint;
(b) determining at least one initial parameter set, each initial parameter set comprising a plurality of initial configuration parameters;
(c) calculating a fitness value for each initial parameter set;
(d) modifying each initial parameter set to produce at least one modified parameter set, said modifying being to improve the fitness value of at least some of the initial parameter sets;
(e) iteratively repeating said modifying until it is determined that a ceasing condition is met;
(f) determining whether at least one said modified parameter set satisfies the at least one configuration constraint;
(g) responsive to said at least one modified parameter set satisfying the at least one configuration constraint, and based on said modified parameter set, generate output data; and
(h) outputting said data.
